(19) United States
(12) Patent Application Publication
(10) Pub. No.: US 2022/0011678 A1
(43) Pub. Date: Jan. 13, 2022

(54) PROCESSING METHOD AND PROCESSING SYSTEM FOR MEASUREMENT DATA OF SEMICONDUCTOR DEVICE, COMPUTER DEVICE AND COMPUTER READABLE STORAGE MEDIUM

(71) Applicant: CHANGXIN MEMORY TECHNOLOGIES, INC., Hefei City (CN)

(72) Inventor: HaiBo GUAN, Hefei (CN)

(21) Appl. No.: 17/396,886

(22) Filed: Aug. 9, 2021

Related U.S. Application Data
(63) Continuation of application No. PCT/CN2021/100086, filed on Jun. 15, 2021.

(30) Foreign Application Priority Data
Jul. 13, 2020 (CN) 202010667779.8

(51) Int. Cl. G03F 7/20; H01L 21/66

(52) U.S. Cl. CPC G03F 7/70508; G03F 7/70625; H01L 22/12; G03F 7/70525; G03F 7/70641

(57) ABSTRACT

Provided are a processing method and processing system for measurement data of a semiconductor device, a computer device and a computer readable storage medium. The above processing method is applied to a processing server and includes: data transmission between the processing server and the measurement machine server is established; a measurement data file on the measurement machine server is acquired; the measurement data file is converted into a preset report, and the preset report is stored in the database of the processing server.

### CROSS-REFERENCE TO RELATED APPLICATIONS

This application is a continuation of International Application No. PCT/CN2021/100086, filed on Jun. 15, 2021, which claims priority to Chinese Application No. 202010667779.8, filed on Jul. 13, 2020 and entitled “Processing Method and Processing System for Measurement Data of Semiconductor Device, and Computer Device”. The contents of International Application No. PCT/CN2021/100086 and Chinese Application No. 202010667779.8 are hereby incorporated by reference in their entireties.

### TECHNICAL FIELD

The application relates to a processing method and processing system for measurement data of a semiconductor device, a computer device and a computer readable storage medium.

### BACKGROUND

In the semiconductor manufacturing process, Critical Dimension (CD) measurement is an indicator of testing the process line width, the semiconductor foundry will use different types of measurement machines for the CD measurement, as well as diverse supporting measurement data analysis report systems.

### SUMMARY

According to multiple embodiments, the first aspect of the present application provides a processing method for measurement data of a semiconductor device, which is applied to a processing server and includes the following operations.

Data transmission between the processing server and the measurement machine server is established.

A measurement date file on the measurement machine server is acquired.

The measurement data file is converted into a preset report, and the preset report is stored in the database of the processing server.

According to multiple embodiments, the second aspect of the present application provides a processing method for measurement data of a semiconductor device, which is applied to a client server and includes the following operations.

Data transmission between the client server and the measurement machine server is established.

The measurement date file on the measurement machine server is acquired.

The data file is converted into a preset report.

According to multiple embodiments, the third aspect of the present application provides a processing system for measurement data of a semiconductor device, which includes a data reading module and a data conversion module.

The data reading module is connected to a measurement machine and is configured to acquire a measurement data file of the measurement machine.

The data conversion module is connected to the data reading module and is configured to convert the measurement data file into a preset report.

According to multiple embodiments, the fourth aspect of the present application provides a computer device, which includes a memory and a processor. The memory stores a computer program. When executed by the processor, the computer program implements the steps of any one of the above methods.

According to multiple embodiments, the fifth aspect of the present application provides a computer-readable storage medium on which a computer program is stored. When executed by a processor, the computer program implements the steps of any one of the above methods.

### BRIEF DESCRIPTION OF THE DRAWINGS

In order to more clearly illustrate the technical solutions in the embodiments of the present application or the traditional technology, the drawings used in the description of the embodiments or the traditional technology will be briefly introduced below. Apparently, the drawings described in the following are some embodiments of the application, for those of ordinary skilled in the art, other drawings can be obtained based on these drawings without creative work.

FIG. 1 is a flowchart of a processing method for measurement data of a semiconductor device in an embodiment.

FIG. 2 is a flowchart of converting a measurement data file into a preset report in a first embodiment.

FIG. 3 is a flowchart of acquiring exposure coordinate data of each and every target chipset on a target wafer in an embodiment.

FIG. 4 is a flowchart of converting a data file into a preset report in a second embodiment.

FIG. 5 is a flowchart of converting a data file into a preset report in a third embodiment.

FIG. 6 is a flowchart of a processing method for measurement data of a semiconductor device in another embodiment.

FIG. 7 is a flowchart of converting a data file into a preset report in a fourth embodiment.

### DETAILED DESCRIPTION

On one hand, a various of supporting measurement data analysis report systems cause waste of IT resources in the foundry and increase maintenance costs. On the other hand, engineers need to switch back and forth between various report systems, and the measurement reports provided by the measurement machines are too simple or very different or do not meet the engineers' requirements for analysis of measurement results, the engineers are required to manually produce the required reports, which will cost the engineers a lot of time and reduce their work efficiency.

In order to facilitate the understanding of the application, the application will be described more comprehensively below with reference to the relevant drawings. The embodiments of the application are illustrated in the drawings. However, this application can be implemented in many different forms and is not limited to the embodiments described herein. On the contrary, these embodiments are provided to make the disclosure of this application more thorough and comprehensive.

Unless otherwise defined, all technical and scientific terms used herein have the same meaning as commonly understood by those skilled in the art of the application. The terms used in the specification of the application herein are only for the purpose of describing specific embodiments, and are not intended to limit the application.

It should be understood that when an element or layer is referred to as being “on”, “adjacent to”, “connected to” or “coupled to” another element or layer, it may be on, adjacent to, connected to, or coupled to the other element or layer directly or by means of an intervening element or layer. In contrast, when an element is referred to as being “directly on”, “directly adjacent to”, “directly connected to” or “directly coupled to” another element or layer, there are no intervening elements or layers. It should be understood that although the terms such as first, second and third may be used to describe various elements, components and/or parts, these elements, components and/or parts should not be limited by these terms. These terms are only used to distinguish one element, component or part from another element, component or part. Therefore, without departing from the teachings of the present disclosure, the first element, component, region or part discussed below may be expressed as the second element, component or part.

Spatial relationship terms such as “under”, “below”, “nether”, “beneath”, “above”, “upper” may be used here to describe the relationship between one element or feature shown and another element or feature in a figure. It should be understood that in addition to the orientation shown in the figure, the spatial relationship terms also include different orientations of the device in use and operation. For example, if the device in the figure is turned over, described as “under the other element” or “below” or “beneath” elements or features will be oriented “on” the other elements or features. Therefore, the exemplary terms “below” and “under” can include both upper and lower orientations. In addition, the device may also include other orientations (for example, a 90-degree rotation or other orientations), and the spatial descriptors used herein are explained accordingly.

When used here, the singular forms of “a”, “an” and “the/this” may also include plural forms, unless the context clearly indicates otherwise. It should also be understood that when the terms “comprise” and/or “include” are used in this specification, the existence of the features, integers, steps, operations, elements and/or components can be determined, but it does not exclude the existence or addition of one or more other features, integers, steps, operations, elements, components and/or groups. And, when used herein, the term “and/or” includes any and all combinations of related listed items.

The embodiments of the disclosure are described here with reference to schematic diagrams of ideal embodiments (and intermediate structure) of the disclosure in form of cross-sectional views, such that changes in the shown shape due to, for example, manufacturing technology and/or tolerances can be expected.

In the semiconductor manufacturing process, CD measurement is an indicator for testing the process line width. At present, there are many CD measurement models, and the measurement report generated by each measurement model is quite different, which causes inconvenience for engineers in data analysis. In addition, in the measurement, the coordinates used by various CD measurement machines are divided into Shot coordinates and Die coordinates. When acquiring the focus energy matrix report, the engineers also need to manually convert the Die coordinates into the Shot coordinates, and get the focus energy matrix report according to the Shot coordinates from conversion, which reduces the work efficiency of the engineers. Therefore, how to make the measurement data obtained by various CD measurement machines use the same program logic to generate the same report has become very important.

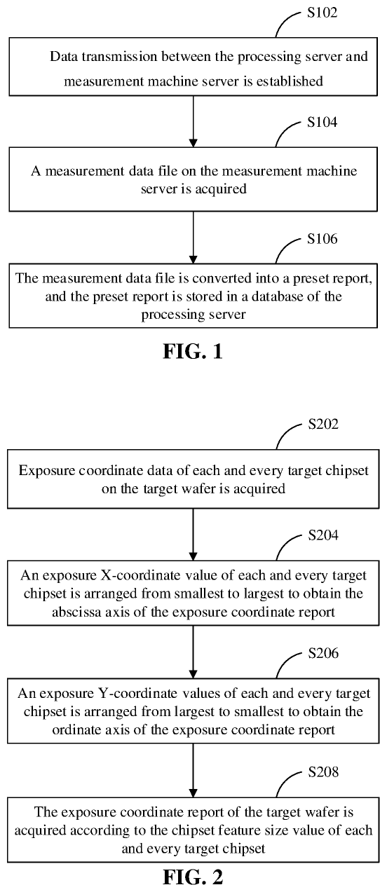

As shown in FIG. 1, in an embodiment, a processing method for measurement data of a semiconductor device is provided, which is applied to a processing server and includes the following operations.

At S102, data transmission between the processing server and measurement machine server is established.

The processing server acquires server information (FTP server information) of all configured measurement machines, and logs in to the measurement machine FTP Server according to login information to establish data transmission between the processing server and the measurement machine server.

At S104, a measurement data file on the measurement machine server is acquired.

After the data transmission between the processing server and the measurement machine server is established, the measurement data file on the measurement machine server is acquired, that is, the file containing the measurement data saved after acquiring the test product of the measurement machine is acquired.

At S106, the measurement data file is converted into a preset report, and the preset report is stored in a database of the processing server.

After acquiring the measurement data file, the processing server converts the measurement data file into a preset report according to the report type set by a user, and stores the preset report in the database of the processing server. The user can call the preset report stored in the database of the processing server as needed, and analyze data in the preset report to obtain a measurement result. There is no need to manually match the measurement data of different measurement machines after acquisition of the measurement data to generate a report in a unified format that meets the requirements, which saves the time for data conversion, improves work efficiency, and can quickly obtain the information stored in measurement data. In addition, the user can log in to the processing server as needed to acquire the required preset reports, avoiding the restriction on the login requirements of the measurement machine.

In an embodiment, the number of measurement machine servers for data transmission with the processing server is greater than or equal to 1. When the number of measurement machine servers for data transmission with the processing server is greater than 1, the measurement machine servers may be servers for the same type of measurement machine, or servers for different types of measurement machines.

As shown in FIG. 2, in an embodiment, the preset report includes an exposure coordinate report, and the step of converting the measurement data file into a preset report includes the following operations.

At S202, exposure coordinate data of each and every target chipset on the target wafer is acquired.

Exposure coordinates (shot coordinates) refer to a coordinate system established in the following manner: the chips on the wafer are divided into groups of A*B chips to obtain a plurality of chipsets, the flat or notch of the wafer is directed upwards, the A*B chips in the center of the wafer being taken as the origin O(0,0), the upward direction from the origin O being the positive direction of the Y axis, and the right direction from the origin O being the positive direction of the X axis.

The wafer measured by the measurement machine is selected as a target wafer, and the exposure coordinate data of each and every target chipset on the target wafer is acquired. The exposure coordinate data includes an exposure X-coordinate value, an exposure Y-coordinate value and a chipset feature size value. That is, the X-coordinate value of each and every target chipset on the target wafer in the shot coordinate system is obtained as the exposure X-coordinate value, and the Y-coordinate value is obtained as the exposure Y-coordinate value, and the feature size value of the target chipset is made corresponding to the exposure X-coordinate value and the exposure Y-coordinate value, the exposure X-coordinate value, the exposure Y-coordinate value and the feature size value are taken as the exposure coordinate data of each and every target chipset.

At S204, the exposure X-coordinate value of each and every target chipset is arranged from smallest to largest as the abscissa axis of the exposure coordinate report.

The exposure X-coordinate values of all target chipsets on the target wafer are arranged from smallest to largest as the abscissa axis of the exposure coordinate report.

At S206, the exposure Y-coordinate value of each and every target chipset is arranged from largest to smallest as the ordinate axis of the exposure coordinate report.

The exposure Y-coordinate values of all target chipsets on the target wafer are arranged from largest to smallest as the ordinate axis of the exposure coordinate report. At this time, a blank exposure coordinate report with abscissa and ordinate axis is obtained.

At S208, the exposure coordinate report of the target wafer is acquired according to the chipset feature size value of each and every target chipset.

The chipset feature size value of each and every target chipset is set in the exposure coordinate report to obtain the exposure coordinate report of the target wafer.

According to the exposure X-coordinate value and exposure Y-coordinate value of each and every target chipset on the target wafer, the chipset feature size value of the target chipset is filled into the blank exposure coordinate report to obtain the exposure coordinate report of the target wafer, that is, a MAP figure of the chipset feature size value of each and every target chipset on the target wafer is obtained. Compared with viewing the measurement data table, the user can intuitively see the actual distribution of the feature size value of the target wafer according to the exposure coordinate report, and perform process adjustment, abnormal analysis and other operations according to the distribution of the feature size value, without the need to manually map the abnormal data in the measurement data table to the target wafer, and then perform data analysis.

The following takes the data in Table 1 as an example to give a detailed description of obtaining the exposure coordinate report of the target wafer. Table 1 is part of the measurement data obtained after a measurement machine measures the feature size of the wafer. The coordinates used by the measurement machine for measurement are Shot coordinates, and the corresponding data is shot coordinate measurement data. After the tested NO.1 wafer is selected as the target wafer, the test data corresponding to NO.1 is obtained, and the exposure X-coordinate values of respective target chipset are arranged from smallest to largest [−11,−5,−3,−2, 0,2,4,6,9,11] as the abscissa axis of the exposure coordinate report, and the exposure Y-coordinate values of respective target chipset are arranged from largest to smallest [19,13,8,7,5,2,0,−2,−8,−13,−14,−15] as the ordinate axis of the exposure coordinate report. Then the chipset feature size values of respective target chipsets in Table 1 are set in the exposure coordinate report to obtain the exposure coordinate report of the target wafer No.1 as shown in Table 2. In Table 2, the user can intuitively see the feature size distribution of each and every part on the target wafer, and quickly analyze the test results without processing the obtained test data, which improves work efficiency and reduces production costs.

TABLE 1

| Chip NO. | Data | P NO. |
|---|---|---|
| −2, −8 | a | 1 |
| 06, −2 | b | 1 |
| 02, 00 | c | 1 |
| 00, 05 | d | 1 |
| −3, 08 | e | 1 |
| 00, 19 | f | 1 |
| 06, 13 | g | 1 |
| 11, 07 | h | 1 |
| 09, −15 | i | 1 |
| 04, −13 | j | 1 |
| −5, −14 | k | 1 |
| −11, 02 | l | 1 |

TABLE 2

| | −11 | −5 | −3 | −2 | 0 | 2 | 4 | 6 | 9 | 11 |
|---|---|---|---|---|---|---|---|---|---|---|
| 19 | | | | | f | | | | | |
| 13 | | | | | | | | g | | |
| 8 | | | e | | | | | | | |
| 7 | | | | | | | | | | h |
| 5 | | | | | d | | | | | |
| 2 | l | | | | | | | | | |
| 0 | | | | | | c | | | | |
| −2 | | | | | | | | b | | |
| −8 | | | | a | | | | | | |
| −13 | | | | | | | j | | | |
| −14 | | k | | | | | | | | |
| −15 | | | | | | | | | i | |

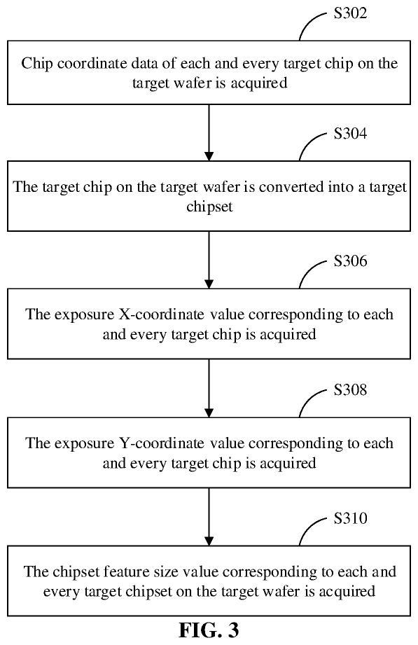

As shown in FIG. 3, in an embodiment, the measurement data file includes a chip coordinate data file, and the step of acquiring the exposure coordinate data of each and every target chipset on the target wafer includes the following operations.

At S302, chip coordinate data of each and every target chip on the target wafer is acquired.

The chip coordinate data of each and every target chip on the target wafer in the measurement data file is acquired. The chip coordinate data includes a chip X-coordinate value, a chip Y-coordinate value, and a chip feature size value. That is, the chip X-coordinate value, the chip Y-coordinate value and the chip feature size value of each and every target chip on the target wafer in the chip coordinate are acquired.

Chip coordinates (die coordinates) refer to a coordinate system established in the following manner: the flat or notch of the wafer is directed upwards, a chip in the center of the wafer being taken as the origin O′(0,0), the upward direction from the origin O′ being the positive direction of the Y axis, the right direction from the origin O′ being the positive direction of the X axis.

At S304, the target chip on the target wafer is converted into a target chipset.

The target chips in A rows and B columns are taken as one target chipset. The target chips on the target wafer are converted into chips in the target chipset. That is, one target chipset is set to include A*B target chips, and the target chips on the target wafer are converted into target chipsets. The values of A and B in the target chipset are constant on the same wafer. For example, 2*3, 4*3, 2*6, 4*2 chips may be selected as one chipset.

At S306, the exposure X-coordinate value corresponding to each and every target chip is acquired.

The sum of the chip X-coordinate value and 1 is divided by A, the ceil function is applied, and 1 is subtracted, so as to obtain the exposure X-coordinate value corresponding to the chip X-coordinate value.

Shot Row=Ceil((Die Row+1)/Shot Die Row Num.)−1; where Die Row is the chip X-coordinate value of the target chip in the die coordinate system; Shot Die Row Num. is the number of rows of target chips in one target chipset; Shot Row is the corresponding exposure X-coordinate value of the target chip in the shot coordinate system. Through the Shot Row formula, the chip X-coordinate value of each and every target chip on the target wafer can be converted into the corresponding exposure X-coordinate value in the shot coordinates.

At S308, the exposure Y-coordinate value corresponding to each and every target chip is acquired.

The sum of the chip Y-coordinate value and 1 is divided by B, the ceil function is applied, and 1 is subtracted, so as to obtain the exposure Y-coordinate value corresponding to the chip Y-coordinate value.

Shot Column=Ceil((Die Column+1)/Shot Die Column Num.)−1; where Die Column is the chip Y-coordinate value of the target chip in die coordinate system; Shot Die Column Num. is the number of columns of target chips in one target chipset; Shot Column is the corresponding exposure Y-coordinate value of the target chip in the shot coordinate system. Through the Shot Column formula, the chip Y-coordinate value of each and every target chip on the target wafer can be converted into the corresponding exposure Y-coordinate value in the shot coordinates.

At S310, the chipset feature size value corresponding to each and every target chipset on the target wafer is acquired.

The feature size values of the target chips with the same exposure X-coordinate value and the same exposure Y-coordinate value are averaged to obtain the feature size value of the chipset corresponding to the exposure X-coordinate value and the exposure Y-coordinate value, so as to obtain the exposure coordinate data corresponding to the target wafer chip coordinate data.

The following is an example of obtaining the exposure coordinate data of the target chipset corresponding to the target chip, in which the target chips on the target wafer are converted into 2*3 target chipsets, namely Shot Die Row Num.=2, Shot Die Column Num.=3, the chip coordinates of the target chips are [1,0], [1,1], [1,2], [0,0], [0,1], [0,2], [1,3], and corresponding chip feature size values are a′, b′, c′, d′, e′, f′, g′. For the chip coordinates [1,0], Die Row=1, Die Column=0; Shot Row=Ceil((1+1)/2 −1=0, Shot Column=Ceil((0+1)/3-1=0, the chipset coordinates corresponding to the chip coordinates [1,0] are [0,0]; in the same way, the chip coordinates [1,1], [1,2], [0,0], [0,1], and [0,2] all correspond to the chipset coordinates [0,0], the chipset feature size value of chipset coordinates [0,0) is M=(a′+b′+c′+d′+e′+f′)/6; for the chip coordinates (1,3), Shot Row=Ceil((1+1)/2)−1=0, Shot Column=Ceil((3+1)/3)−1=1, the chipset coordinates corresponding to the chip coordinates (1,3) are (0,1). In the same way, the target chipset corresponding to each and every target chip on the target wafer and the exposure coordinate data corresponding to the target chipset can be obtained.

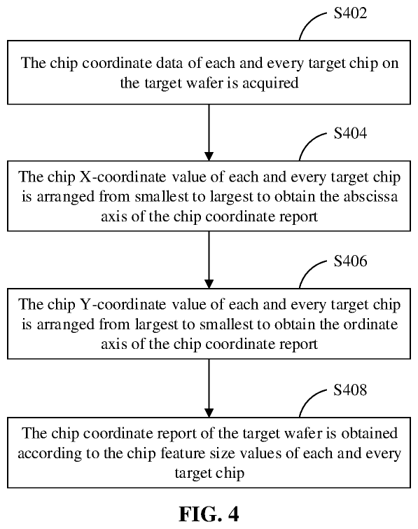

As shown in FIG. 4, in an embodiment, the measurement data file includes a chip coordinate data file, the preset report includes a chip coordinate report, and the step of converting the data file into a preset report includes the following operations.

At S402, the chip coordinate date of each and every target chip on the target wafer is acquired.

The wafer measured by the measurement machine is selected as the target wafer, and the chip coordinate data of each and every target chip on the target wafer is acquired. The chip coordinate data includes a chip X-coordinate value, a chip Y-coordinate value, and a chip feature size value. That is, the X-coordinate value and Y-coordinate value of each and every target chip on the target wafer in the die coordinate system are acquired to obtain the chip X-coordinate value and the chip Y-coordinate value, and the feature size value of the target chip is made corresponding to the chip X-coordinate value and the chip Y-coordinate value, to obtain exposure coordinate data of each and every target chip.

At S404, the chip X-coordinate value of each and every target chip is arranged from smallest to largest to obtain the abscissa axis of the chip coordinate report.

The chip X-coordinate values of all target chips on the target wafer are arranged from smallest to largest as the abscissa axis of the chip coordinate report.

At S406, the chip Y-coordinate value of each and every target chip is arranged from largest to smallest to obtain the ordinate axis of the chip coordinate report.

The chip Y-coordinate values of all target chips on the target wafer are arranged from largest to smallest to obtain the ordinate axis of the chip coordinate report, and the blank chip coordinate report with abscissa and ordinate axis is obtained.

At S408, the chip coordinate report of the target wafer is obtained according to the chip feature size value of each and every target chip.

The chip feature size value of each and every target chip is set in the chip coordinate report to obtain the chip coordinate report of the target wafer.

According to the chip X-coordinate value and chip Y-coordinate value of each and every target chip on the target wafer, the chip feature size value of the target chip is filled into the blank chip coordinate report to obtain the chip coordinate report of the target wafer, that is, a MAP figure of the chip feature size value of each and every target chip on the target wafer is obtained. Compared with viewing the measurement data table, user can intuitively see the actual distribution of the feature size value of the target wafer according to the chip coordinate report, and according to the distribution of the feature size values, perform process adjustment, abnormal analysis and other operations according to the distribution of the feature size values, without the need to manually map the abnormal data in the measurement data table to the target wafer, and then perform data analysis.

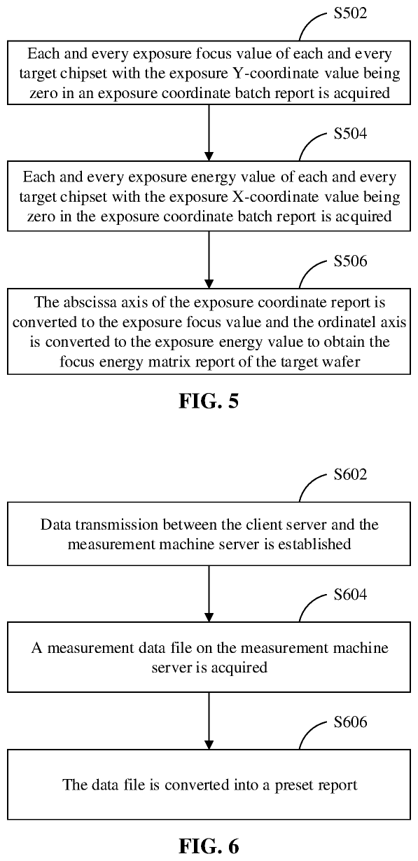

As shown in FIG. 5, in an embodiment, the preset report further includes a focus energy matrix report, and the step of converting the data file into a preset report further includes the following operations.

At S502, each and every exposure focus value in the exposure coordinate batch report of the target chipset with the exposure Y-coordinate value being zero is acquired.

The corresponding exposure focus value of each and every target chipset with the exposure Y-coordinate value being zero on the target wafer in the exposure coordinate batch report, that is, the exposure focus value of each and every target chipset of the exposure Y-coordinate value in the exposure coordinate batch report, is acquired. The exposure coordinate batch report refers to the exposure focus value report and exposure energy value report for the exposure process of the exposure machine on the target wafer. The exposure focus value report and exposure energy value report are shot coordinate reports.

At S504, each and every exposure energy value in the exposure coordinate batch report of the target chipset with the exposure X-coordinate value being zero is acquired.

The corresponding exposure energy value of each and every target chipset with the exposure X-coordinate value being zero on the target wafer in the exposure coordinate batch report, that is, the exposure energy value of each and every target chipset of the exposure X-coordinate value in the exposure coordinate batch report, is acquired.

At S506, the abscissa axis of the exposure coordinate report is converted to the exposure focus value, and the ordinate axis is converted to the exposure energy value, so as to obtain the focus energy matrix report of the target wafer.

Each and every exposure focus value is taken as the abscissa axis of the exposure coordinate report, and each and every exposure energy value is taken as the ordinate axis of the exposure coordinate report, so as to obtain the focus energy matrix report of the target wafer.

For example, the target chipset coordinates in the exposure coordinate report are [−1,0], the corresponding Focus value in the Focus type of the exposure coordinate batch report, that is, the exposure machine Lot report, is −0.02, and in the exposure coordinate report, the −1 on the abscissa axis will be replaced with −0.02; by analogy, the abscissa axis of the entire exposure coordinate report is replaced with the Focus value in the Focus type of the exposure machine Lot report. In the same way, the ordinate axis of the entire exposure coordinate report is replaced with the Energy value in the Energy type of the exposure machine Lot report, to obtain the focus energy matrix report corresponding to the exposure coordinate report.

In an embodiment, before each and every exposure focus value of the target chipset with the exposure Y-coordinate value being zero in the exposure coordinate batch report is acquired, the following operation is further included.

The exposure batch report of the target wafer is rotated to make the ordinate axis of the exposure batch report consistent with the Y-axis direction of the exposure coordinates to obtain the exposure coordinate batch report of the target chipset in the exposure coordinates report; and the exposure coordinate batch report includes an exposure focus value report and an exposure energy value report.

There is a certain angle between the Y-axis coordinate when the exposure machine exposes the target wafer and the positive Y-axis direction of the exposure coordinates, that is, there is a certain angle (Scanner Notch) between the exposure batch report of the exposure machine and the positive Y-axis direction of the exposure coordinates. Before the focus energy matrix report of the target wafer is obtained, it is necessary to rotate the exposure batch report to the exposure coordinate batch report, and match the exposure coordinate report with the exposure coordinate batch report to obtain the focus energy matrix of the target wafer report. For example, if the Scanner Notch is 90°, the exposure batch report is rotated counterclockwise by 90°; if the Scanner Notch is 270°, the exposure batch report is rotated counterclockwise by 270°; if the Scanner Notch is 180°, the exposure batch report is rotated counterclockwise/clockwise by 180°.

In an embodiment, the method further includes: a test picture corresponding to the measurement data file is acquired, and the test picture is stored in a network storage of the processing server.

The above-mentioned processing method for measurement data of a semiconductor device is applied to a processing server, and includes: data transmission between the processing server and the measurement machine server is established; measurement date file on the server of the measurement machine is acquired; the measurement data file is converted into a preset report, and the preset report is stored in the database of the processing server. In this application, the measurement data file is converted into a preset report, and the preset report is stored in the database of the processing server. The engineer can call and view the preset report in the processing server database as needed, which avoids the problem that the engineer takes time to deal with the measurement data when viewing the measurement reports provided by different measurement machines, due to large differences between measurement reports or that the measurement reports do not meet the requirements of measurement result analysis.

As shown in FIG. 6, an embodiment, a processing method for measurement data of a semiconductor device is provided, which is applied to a client server, and includes the following operations.

At S602, data transmission between the client server and the measurement machine server is established.

The client server acquires server information (FTP server information) of a measurement machine to be connected, and logs in to the measurement machine FTP Server according to the login information to establish the data transmission between the client server and the measurement machine server.

At S604, the measurement data file on the measurement machine server is acquired.

After the data transmission between the client server and the measurement machine server is established, the measurement data file on the measurement machine server is acquired, that is, the file containing the measurement data saved after the measurement machine test the product is acquired.

At S606, the data file is converted into a preset report.

After acquiring the measurement data file, the client server converts the measurement data file into a preset report according to the report type set by a user. The user can set the data type of the preset report as needed, and after obtaining the preset report from the client server, analyze the data in the preset report to obtain a measurement result. There is no need to manually match the measurement data of different measurement machines after obtaining the measurement data to generate a report in a unified format that meets the requirements, which saves the time for data conversion, improves work efficiency, and quickly obtains information stored in measurement data. The user can log in to the client server as needed to acquire the required preset reports, avoiding the restriction on the login requirements of the measurement machine.

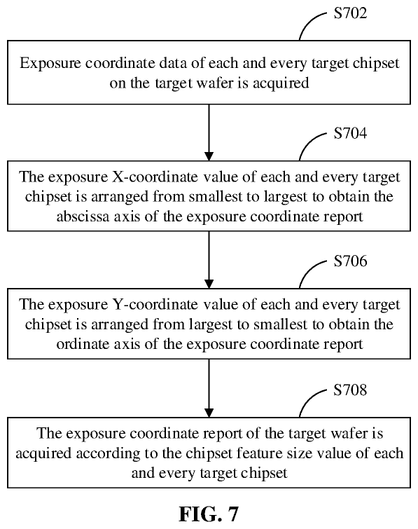

As shown in FIG. 7, in an embodiment, the preset report includes an exposure coordinate report, and the step of converting a data file into a preset report includes the following operations.

At S702, exposure coordinate data of each and every target chipset on the target wafer is acquired.

The wafer measured by the measurement machine is selected as the target wafer, and the exposure coordinate data of each and every target chipset on the target wafer is acquired. The exposure coordinate data includes an exposure X-coordinate value, an exposure Y-coordinate value and a chipset feature size value.

At S704, the exposure X-coordinate value of each and every target chipset is arranged from smallest to largest to obtain the abscissa axis of the exposure coordinate report.

At S706, the exposure Y-coordinate value of each and every target chipset is arranged from largest to smallest to obtain the ordinate axis of the exposure coordinate report.

At S708, the chipset feature size value of each and every target chipset is set in the exposure coordinate report to obtain the exposure coordinate report of the target wafer.

The user can intuitively see the actual distribution of the feature size value of the target wafer according to the exposure coordinate report, and perform process adjustment, abnormal analysis and other operations according to the distribution of feature size values, without the need to manually map the abnormal data in the measurement data table to the target wafer, and then perform data analysis.

In an embodiment, the measurement data file includes a chip coordinate data file, and the step of acquiring the exposure coordinate data file of each and every target chipset on the target wafer includes the following operations.

Chip coordinate data of each and every target chip on the target wafer is acquired, where the chip coordinate data includes a chip X-coordinate value, a chip Y-coordinate values, and a chip feature size value.

Target chips in A rows and B columns are taken as a target chipset.

The sum of the chip X-coordinate value and 1 is divided by A, the ceil function is applied, and 1 is subtracted, to obtain the exposure X-coordinate value corresponding to the chip X-coordinate value;

The sum of the chip Y-coordinate value and 1 is divided by B, the ceil function is applied, and 1 is subtracted, to obtain the exposure Y-coordinate value corresponding to the chip Y-coordinate value;

The feature size values of the target chips with the same exposure X-coordinate value and the same exposure Y-coordinate value are averaged to obtain the chipset feature size value corresponding to the exposure X-coordinate value and the exposure Y-coordinate value.

In an embodiment, the preset report further includes a focus energy matrix report, and the step of converting the measurement data file into a preset report further includes the following operations.

Each and every exposure focus value of the target chipset in the exposure coordinate batch report with each and every exposure Y-coordinate value being zero is acquired.

Each and every exposure energy value of the target chipset in the exposure coordinate batch report with each and every exposure X-coordinate value being zero is acquired.

The focus energy matrix report of the target wafer is obtained by taking each and every exposure focus value as the abscissa axis of the exposure coordinate report, and taken each and every exposure energy value as the ordinate axis of the exposure coordinate report.

In an embodiment, before each and every exposure focus value of the target chipset with the exposure Y-coordinate value being zero in the exposure coordinate batch report is included, a step is further included.

An exposure batch report of a target wafer is rotated to make the ordinate axis of the exposure batch report consistent with the Y-axis direction of the exposure coordinates to obtain the exposure coordinate batch report of the target chipset in the exposure coordinates.

The exposure coordinate batch report includes an exposure focus value report and an exposure energy value report.

It is stated here that the above-mentioned processing method for measurement data of a semiconductor device applied to the client server is similar to the processing method for measurement data of a semiconductor device applied to the processing server, the technical features and beneficial effects in the above embodiments of the processing method for measurement data of a semiconductor device applied to the processing server are all applicable to the embodiments of the processing method for measurement data of a semiconductor device applied to the client servers.

The above-mentioned processing method for measurement data of a semiconductor device, applied to a client server, includes: data transmission between the client server and the measurement machine server is established; a measurement data file on the measurement machine server is acquired; the data file is converted into a preset report. This application converts the measurement data file into a preset report, which avoids the problem that the engineer takes time to deal with the measurement data when viewing measurement reports provided by different measurement machines, due to large differences between measurement reports or that the measurement reports do not meet the requirements of measurement result analysis.

In an embodiment, a processing system for measurement data of a semiconductor device is provided, which includes a data reading module and a data conversion module.

The data reading module is connected to a measurement machine and is configured to acquire a measurement data file of the measurement machine.

The data conversion module is connected to the data reading module and is configured to convert the measurement data file into a preset report.

In an embodiment, the preset report includes an exposure coordinate report; the data conversion module is configured to acquire the exposure coordinate data of each and every target chipset on the target wafer in the measurement data file, and the exposure coordinate data includes an exposure X-coordinate value, an exposure Y-coordinate value and a chipset feature size value;

The data conversion module is also configured to: arrange the exposure X-coordinate value of each and every target chipset from smallest to largest to obtain the abscissa axis of the exposure coordinate report; arrange the exposure Y-coordinate value of each and every target chipset from largest to smallest to obtain the ordinate axis of the exposure coordinate report; set the chipset feature size value of each and every target chipset in the exposure coordinate report to obtain the exposure coordinate report of the target wafer.

It is stated here that the processing system for measurement data of a semiconductor device of the present disclosure has a one-to-one correspondence with the processing method for measurement data of a semiconductor device, the technical features and beneficial effects in the above embodiments of the processing method for measurement data of a semiconductor device are all applicable to the embodiments of the processing system for measurement data of a semiconductor device.

The above-mentioned processing system for measurement data of a semiconductor device includes a data reading module and a data conversion module. The data reading module is connected to the measurement machine and is configured to acquire the measurement data file of the measurement machine. The data conversion module is connected to the data reading module and is configured to convert the measurement data file into the preset report. This application configures the data conversion module to convert the measurement data file into a preset report, which avoids the problem that the engineer takes time to deal with the measurement data when viewing measurement reports provided by different measurement machines, due to large differences between measurement reports or that the measurement reports do not meet the requirements of measurement results analysis.

In an embodiment, a computer device is provided, which includes a memory and a processor. The memory stores a computer program. When executing the computer program, the processor implements the steps of any one of the methods described above.

In an embodiment, a computer-readable storage medium is provided, and a computer program is stored thereon. When executed by a processor, the computer program implements the steps of any one of the methods described above.

The above-mentioned computer device and computer-readable storage medium include a memory and a processor, the memory stores a computer program, and the processor implements the steps of any one of the above-mentioned methods when the computer program is executed by the processor. This application converts the measurement data file into a preset report, which avoids the problem that the engineer takes time to deal with the measurement data when viewing measurement reports provided by different measurement machines, due to large differences between measurement reports or that measurement reports do not meet the requirements of measurement result analysis.

The technical features of the embodiments can be combined arbitrarily. In order to make the description concise, not all possible combinations of the technical features of the embodiments are described. However, as long as there is no conflict, the combinations of these technical features should be considered as the scope described in this specification.

The above-mentioned embodiments only illustrate several implementation modes of this application, and their description is more specific and detailed, but they should not be interpreted as the limitation on the scope of the patent application. It should be pointed out that for those skilled in the art, without departing from the concept of this application, several modifications and improvements can be made, and these all fall within the protection scope of this application. Therefore, the scope of protection of the patent in this application shall be subject to the appended claims.

What is claimed is:

1. A processing method for measurement data of a semiconductor device, applied to a processing server, comprising:
establishing data transmission between the processing server and measurement machine server;
acquiring a measurement data file on the measurement machine server; and
converting the measurement data file into a preset report, and storing the preset report in a database of the processing server.

2. The processing method according to claim 1, wherein the preset report comprises an exposure coordinate report, and the step of converting the measurement data file into a preset report comprises:
acquiring exposure coordinate data of each and every target chipset on a target wafer, wherein the exposure coordinate data comprises an exposure X-coordinate value, an Y exposure coordinate value, and a chipset feature size value;
arranging the exposure X-coordinate value of the each and every target chipset from smallest to largest as an abscissa axis of the exposure coordinate report;
arranging the exposure Y-coordinate values of the each and every target chipset from largest to smallest as an ordinate axis of the exposure coordinate report; and
setting the chipset feature size value of the each and every target chipset in the exposure coordinate report to obtain the exposure coordinate report of the target wafer.

3. The processing method according to claim 2, wherein the measurement data file comprises a chip coordinate data file, and the step of acquiring the exposure coordinate data of each and every target chipset on a target wafer comprises:
acquiring chip coordinate data of the each and every target chip on the target wafer, wherein the chip coordinate data includes a chip X-coordinate value, a chip Y-coordinate value, and a chip feature size value;
taking target chips in A rows and B columns as one target chipset;
dividing a sum of the chip X-coordinate value and 1 by A, applying a ceil function and subtracting 1 to obtain exposure X-coordinate value corresponding to the chip X-coordinate value;
dividing a sum of the chip Y-coordinate value and 1 by B, applying a ceil function and subtracting 1 as exposure Y-coordinate value corresponding to the Y chip coordinate value; and
averaging a feature size value of a target chip with a same exposure X-coordinate value and a same exposure Y-coordinate value to obtain a chipset feature size value corresponding to the exposure X-coordinate value and the exposure Y-coordinate value.

4. The processing method according to claim 2, wherein the preset report further comprises a focus energy matrix report, and the step of converting the data file into a preset report further comprises:
acquiring each and every exposure focus value of each and every target chipset with the exposure Y-coordinate value being zero in an exposure coordinate batch report;
acquiring each and every exposure energy value of each and every target chipset with the exposure X-coordinate value being zero in an exposure coordinate batch report; and
obtaining the focus energy matrix report of the target wafer by taking the each and every exposure focus value as the abscissa axis of the exposure coordinate report and taking the each and every exposure energy value as ordinate axis of the exposure coordinate report.

5. The processing method according to claim 4, before the acquiring each and every exposure focus value of each and every target chipset with the exposure Y-coordinate value being zero in an exposure coordinate batch report, the method further comprises:
rotating an exposure batch report of the target wafer to make the ordinate axis of the exposure batch report consistent with a Y-axis direction of exposure coordinates to obtain the exposure coordinate batch report of the target chipset in the exposure coordinates;
wherein the exposure coordinate batch report comprises an exposure focus value report and an exposure energy value report.

6. The processing method according to claim 1, wherein the method further comprises:
obtaining a test picture corresponding to the measurement data file, and storing the test picture in a network storage of the processing server.

7. The processing method according to claim 1, wherein a number of the measurement machine server for data transmission with the processing server is greater than or equal to 1.

8. A processing method for measurement data of semiconductor device, applied to a client server, comprises:
establishing data transmission between the client server and a measurement machine server;
obtaining a measurement data file on the measurement machine server; and
converting the data file into a preset report.

9. The processing method according to claim 8, wherein the preset report comprises an exposure coordinate report, and the step of converting a data file into a preset report comprises:
acquiring exposure coordinate data of each and every target chipset on a target wafer, wherein the exposure coordinate data comprises an exposure X-coordinate value, an exposure Y-coordinate value, and a chipset feature size value;
arranging the exposure X-coordinate value of the each and every target chipset from smallest to largest as an abscissa axis of the exposure coordinate report;
arranging the exposure Y-coordinate value of the each and every target chipset from largest to smallest as an ordinate axis of the exposure coordinate report; and
setting the chipset feature size value of the each and every target chipset in the exposure coordinate report to obtain the exposure coordinate report of the target wafer.

10. The processing method according to claim 9, wherein the measurement data file comprises a chip coordinate data file, and the step of acquiring exposure coordinate data file of each and every target chipset on a target wafer comprises:
acquiring chip coordinate data of the each and every target chip on the target wafer, wherein the chip coordinate data comprises a chip X-coordinate value, a chip Y-coordinate value, and a chip feature size value;
taking the target chips in A rows and B columns as one target chipset;
dividing a sum of the chip X-coordinate value and 1 by A, applying a ceil function and subtracting 1 to obtain an exposure X-coordinate value corresponding to the chip X-coordinate value;
dividing a sum of the chip Y-coordinate value and 1 by B, applying the ceil function and subtracting 1 to obtain an exposure Y-coordinate value corresponding to the chip Y-coordinate value; and
averaging a feature size value of a target chip with a same exposure X-coordinate value and a same exposure Y-coordinate value to obtain a chipset feature size value corresponding to the exposure X-coordinate value and the exposure Y-coordinate value.

11. The processing method according to claim 9, wherein the preset report further comprises a focus energy matrix report, and the step of converting the measurement data file into a preset report further comprises:
acquiring each and every exposure focus value of the each and every target chipset with an exposure Y-coordinate value being zero in an exposure coordinate batch report;
acquiring each and every exposure energy value of the each and every target chipset with an exposure X-coordinate value being zero in an exposure coordinate batch report; and
obtaining the focus energy matrix report of the target wafer by taking the each and every exposure focus value as the abscissa axis of the exposure coordinate report, and taking the each and every exposure energy value as the ordinate axis of the exposure coordinate report.

12. The processing method according to claim 11, wherein before the acquiring each and every exposure focus value of the each and every target chipset with an exposure Y-coordinate value being zero in an exposure coordinate batch report, the method further comprises:
rotating an exposure batch report of a target wafer to make the ordinate axis of the exposure batch report consistent with the Y-axis direction of the exposure coordinates to obtain the exposure coordinate batch report of the target chipset in the exposure coordinates;
wherein the exposure coordinate batch report comprises an exposure focus value report and an exposure energy value report.

13. A processing system for measurement data of a semiconductor device, which comprises:
a data reading module, which is connected to a measurement machine and is configured to acquire a measurement data file of the measurement machine; and
a data conversion module, which is connected to the data reading module and is configured to convert the measurement data file into a preset report.

14. The processing system according to claim 13, wherein the preset report comprises an exposure coordinate report;
the data conversion module is configured to acquire an exposure coordinate data of each and every target chipset on a target wafer in a measurement data file, and the exposure coordinate data comprises an exposure X-coordinate value, an exposure Y-coordinate value, a chipset feature size value; and
the data conversion module is further configured to arrange the exposure X-coordinate value of the each and every target chipset from smallest to largest as an abscissa axis of the exposure coordinate report; and arrange the exposure Y-coordinate value of the each and every target chipset from largest to smallest as an ordinate axis of an exposure coordinate report; setting the chipset feature size value of the each and every target chipset in the exposure coordinate report to obtain the exposure coordinate report of the target wafer.

15. A computer device, comprising a memory and a processor, the memory storing a computer program, wherein when executing the computer program, the processor implements the steps of the method according to claim 1.

16. A computer readable storage medium, on which a computer program is stored, wherein when executed by a processor, the computer program implements the steps of the method according to claim 1.
